(19) United States
(12) Patent Application Publication
(10) Pub. No.: US 2008/0150561 A1
(43) Pub. Date: Jun. 26, 2008

(54) Device and method for testing semiconductor element, and manufacturing method thereof

(75) Inventors: Chew Hwee-Seng Jimmy, Singapore (SG); Ong Chee Kian, Singapore (SG); Wang Zhiping, Singapore (SG); Ma Zhaohui, Singapore (SG); Abd. Razak Bin Chichik, Singapore (SG)

Correspondence Address: RABIN & Berdo, PC, 1101 14TH STREET, NW, SUITE 500, WASHINGTON, DC, 20005, US

(73) Assignee: ADVANPACK SOLUTIONS PTE LTD., Singapore (SG)

(21) Appl. No.: 12/003,425

(22) Filed: Dec. 26, 2007

(30) Foreign Application Priority Data
Dec. 22, 2006 (TW) 95148521

(51) Int. Cl. G01R 31/26; H05K 3/42

(52) U.S. Cl. 324/755; 29/852

(57) ABSTRACT

A device and a method for testing a semiconductor element, and manufacturing method thereof are provided. The apparatus includes a substrate and a conductive macromolecular elastic structure. The conductive macromolecular elastic structure is disposed on the substrate and defines a receiving space for receiving a conductive bump of the semiconductor element in order to test the semiconductor element.

This application claims the benefit of Taiwan application Serial No. 95148521, filed Dec. 22, 2006, the subject matter of which is incorporated herein by reference.

### BACKGROUND OF THE INVENTION

1. Field of the Invention

The invention relates in general to a device and method for testing semiconductor element, and manufacturing method thereof, and more particularly to a device and method for testing semiconductor element via a contact test process, and manufacturing method thereof.

2. Description of the Related Art

Along with constantly developing of technology, various types of electronic products are produced to promote development of the semiconductor industry. The semiconductor element is a kind of subtle and expensive electronic device. Owing that it is difficult to repair a semiconductor element of poor quality or find out the reason why its quality is worsen, in a manufacturing process or before being sent out of the factory, the semiconductor element requires a series of strict test procedures to ensure its quality.

A conventional apparatus of testing a semiconductor element includes a test substrate with a test pad. The test pad is a conductive bump electrically coupled to the semiconductor element by a contact way and is used for various electricity tests. Generally speaking, electrically coupling by wielding is quite inconvenient and can even damage the semiconductor element or the test substrate. Therefore, a majority of test process of semiconductor element uses a contact way of electrical coupling but not the wielding way of electrical coupling.

However, in a test process, test accuracy may be greatly reduced due to poor contact between the conductive bump and test pad. There are many reasons which cause the poor contact between the conductive bump and the test pad, such as the conductive bumps have different length or width, the test pad is worn and torn, or the test substrate is deformed. These factors are difficult to control, usually lead to a serious test error and reduce accuracy of the test process. Conventionally, a number of repeated test operations are performed to ensure the accuracy of the test process, which in turn largely increases process time. Therefore, how to improve accuracy of the semiconductor-element test process is an essential subject of the present relevant research and development.

### SUMMARY OF THE INVENTION

The invention is directed to a device and method for testing semiconductor element, and manufacturing method thereof. According to an aspect of the embodiments of the invention, a conductive macromolecular elastic structure with electric conductivity and elasticity is used as a conductive pad such that in the test process of semiconductor element, the semiconductor element can be electrically coupled to the test device very well without being affected by the factors of length or width diversity of conductive bumps or substrate wear and tear. Therefore, the accuracy of test process can be largely improved.

According to another aspect of the embodiments of the present invention, an apparatus of testing a semiconductor element is provided. The apparatus comprises a substrate and a conductive macromolecular elastic structure. The conductive macromolecular elastic structure is disposed on the substrate and defines a receiving space for receiving a conductive bump of the semiconductor element in order to test the semiconductor element.

According to another aspect of the embodiments of the present invention, a method of manufacturing a semiconductor-element testing apparatus is provided. The method comprises the following steps. Firstly, a substrate is pervaded. Afterward a conductive macromolecular elastic layer is formed on the substrate, wherein the conductive macromolecular elastic layer has a receiving space for receiving a conductive bump of the semiconductor element in order to test the semiconductor element.

According to another aspect of the embodiment of the present invention, an apparatus of testing a semiconductor element is provided. The apparatus comprises a substrate and a conductive macromolecular elastic structure. The conductive macromolecular elastic structure is disposed on the substrate. The conductive macromolecular elastic structure comprises a receiving unit with two side contact positions. The receiving unit can be stretched out by an external force and a shrink back as the external force is removed.

According to another aspect of the embodiment of the present invention, a method of testing a semiconductor element is provided. The method comprises the following steps. Firstly, a semiconductor element with at least a conductive bump is provided. Afterward, a substrate with a conductive macromolecular elastic structure is provided, the conductive macromolecular elastic structure having a receiving space and being electrically coupled to a test equipment. And the conductive bump of the semiconductor element is inserted into the receiving space such that the conductive bump and the conductive macromolecular elastic structure form a connection relationship for signal transmission. Then, a power is supplied to the semiconductor element such that the semiconductor element can transmit a signal to the test equipment via the conductive macromolecular elastic structure. Afterward, the signal is read by the test equipment and whether the semiconductor element has a normal operation according to a predetermined specification is determined.

The invention will become apparent from the following detailed description of the preferred but non-limiting embodiments. The following description is made with reference to the accompanying drawings.

### BRIEF DESCRIPTION OF THE DRAWINGS

FIG. 1 is a schematic diagram of a semiconductor-element test device and a semiconductor element according to a first embodiment of the invention.

FIG. 2 is a schematic diagram of electrical coupling between the semiconductor-element test device and semiconductor element of FIG. 1.

FIG. 3 shows a flowchart of the method of manufacturing the semiconductor-element test device according to the first embodiment of the invention.

FIGS. 4A˜4I are schematic diagrams of the steps in FIG. 3.

FIG. 5 is a schematic diagram of the semiconductor-element test device according to the second embodiment of the invention.

FIG. 6 is a flowchart of the method of manufacturing the semiconductor-element test device according to the second embodiment of the invention, and

FIGS. 7A˜7B are schematic diagrams of the steps in FIG. 6.

FIG. 8 is a schematic diagram of another semiconductor-element test device according to the invention.

FIG. 9 is a schematic diagram of another semiconductor-element test device according to the invention.

FIG. 10 is a schematic diagram of another semiconductor-element test device according to the invention.

FIG. 11 is a schematic diagram of another semiconductor-element test device according to the invention.

### DETAILED DESCRIPTION OF THE INVENTION

### Embodiment One

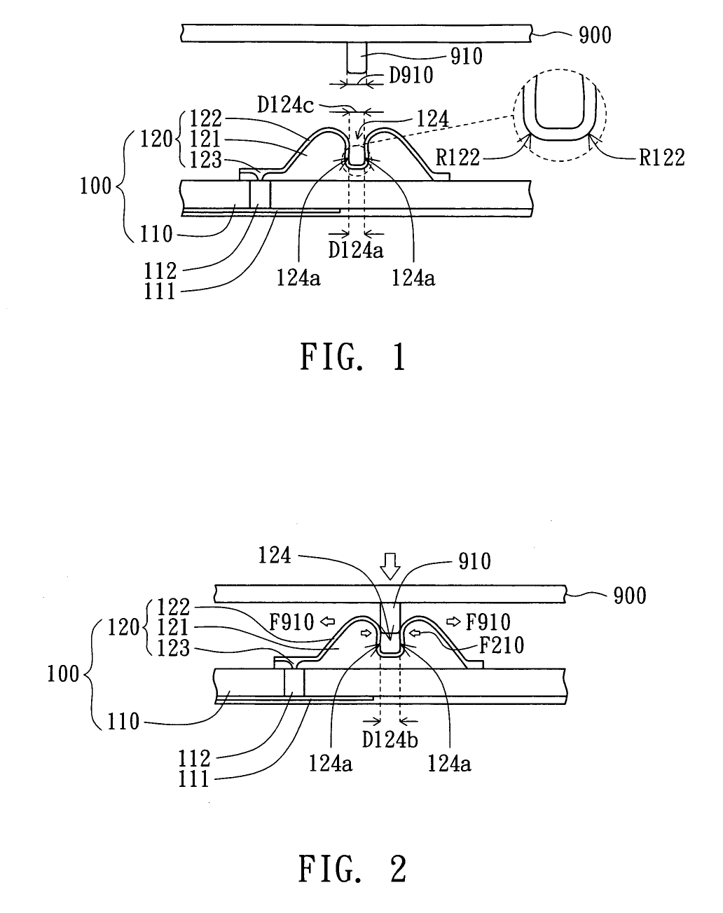

Referring to FIG. 1, a schematic diagram of a semiconductor-element test device 100 and a semiconductor element 900 according to a first embodiment of the invention is shown. The semiconductor-element test device 100 includes a substrate 110 and at least a conductive macromolecular elastic structure 120. The conductive macromolecular elastic structure 120 is disposed on the substrate 110. The conductive macromolecular elastic structure 120 defines a receiving space 124. Generally speaking, owing that the to-be-tested semiconductor element 900 has a number of conductive bumps to be tested (which are conductive pillar bumps in the embodiment), there are also a number of corresponding conductive macromolecular elastic structures 120. For convenience of illustration, only a conductive pillar bump of the semiconductor element 900 and a conductive macromolecular elastic structure 120 are taken as an example.

The conductive macromolecular elastic structure 120 of the embodiment consists of an insulated macromolecular elastomer 121 and a conductive layer 122. The insulated macromolecular elastomer 121 is disposed on the substrate 110. The conductive layer 122 is disposed on the insulated macromolecular elastomer 121. The insulated macromolecular elastomer 121 has elasticity.

Besides, the insulated macromolecular elastomer 121 of the embodiment has a two-peak structure and the conductive layer 122 formed along the structure of the insulated macromolecular elastomer 121 has also a shape of two peaks. A receiving space 124 is formed between the two peaks. In fact, the conductive macromolecular elastic structure 120 is not necessary to have a two-peak structure and can have a flat top as long as there is the receiving space 124 formed in the conductive macromolecular elastic structure 120. The conductive layer 122 is formed along at least a side wall 124a of the receiving space 124. In the embodiment, the conductive layer 122 is formed along two opposite side walls 124a of the receiving space 124.

Referring to FIG. 2, a schematic diagram of electrical coupling between the semiconductor-element test device 100 and semiconductor element 900 of FIG. 1 is shown. The receiving space 124 is for receiving a conductive pillar bump 910 of the semiconductor element 900 for testing the semiconductor element 900. Due to elasticity of the conductive macromolecular elastic structure 120, the receiving space 124 has an ability of expanding and shrinking in some extent. Therefore, when the conductive pillar bump 910 is inserted into the receiving space 124, the receiving space 124 stretches out. By doing this, the conductive pillar bump 910 can be electrically coupled to the semiconductor element 900 in a contact way. In the embodiment, the conductive macromolecular elastic structure 120 is stretched out due to an external force applied by the inserted conductive pillar bump 910. When the conductive pillar bump 910 is removed, the conductive macromolecular elastic structure 120 shrinks back due to removal of the external force.

That is to say, in the embodiment, the width D124a of the receiving space 124 of FIG. 1 is slightly smaller than the width D124b of the receiving space 124 of FIG. 2. The receiving apace 124 can be expanded and contracted between the width D 124a and the width D124b.

The conductive macromolecular elastic structure 120 of the embodiment is made of polydimethylsiloxane (PDMS). The elastic modulus of the PDMS is 0.2˜9.4 MPA and is preferably 0.7˜3.0 MPA. The substrate 110 of the embodiment is made of ceramics whose elastic modulus is 10˜100 GPA. Therefore, the elasticity of the substrate 110 is smaller than that of the conductive macromolecular elastic structure 120 so as to support the conductive pillar bump 910 to be inserted.

Besides, the conductive macromolecular elastic structure 120 has a coefficient of expansion about 60˜350 PPM and in the temperature about −55° C.˜155° C., its coefficient of expansion is about 300 PPM. The expansion coefficient of the substrate 110 is about 3˜5 PPM.

The conductive device 900 of the embodiment is exemplified to be a conductive chip for illustration. However, any one who is skilled in the related art can realize that the conductive device 900 and the conductive pillar bump 910 are not limited thereto. The conductive bump can also have other type of conductive mechanism, such as a solder ball. Moreover, the semiconductor element can also be a wafer, a bare chip, a cut chip or a fabricated chip structure.

As shown in FIG. 2, the conductive macromolecular elastic structure 120 includes a receiving device having at least two side contact positions. The above receiving space 124 is formed between the two side contact positions. When the conductive pillar bump 910 of the conductive device 900 is inserted into the receiving space 124, the conductive pillar bump 910 pushes the two side contact positions of the receiving device. The receiving space 124 stretches out as applied by the pushing force F910 of the conductive pillar bump 910. In the meanwhile, the receiving space 124 applies a restoring force F210 to the conductive pillar bump 910 to firmly clamp the conductive pillar bump 910. When the conductive pillar bump 910 is removed from the receiving space 124, the pushing force F910 supplied by the conductive pillar bump 910 is removed and the receiving space 124 shrinks back.

As mentioned above, the conductive layer 122 has electric conductivity and the insulated macromolecular elastomer 121 has elasticity. When the conductive pillar bump 910 is inserted into the receiving space 124, the conductive pillar bump 910 is inserted with its two sides against the conductive layer 122 and the insulated macromolecular elastomer 121 is deformed such that the conductive pillar bump 910 is tightly attached to the conductive layer 122 without any gap. As a result, not only the contact area of the conductive pillar bump 910 and conductive layer 122 is increased, but also the poor contact condition of the two devices can be reduced.

Preferably, as shown in FIG. 1, the minimal radius D124c of the receiving space 124 is smaller than the maximal radius D910 of the conductive pillar bump 910. Therefore, when the conductive pillar bump 910 is inserted into the receiving space 124, the conductive pillar bump 910 is not loose relative to the receiving space 124 and no gap occurs between the conductive pillar bump 910 and the side walls 124a. The minimal radius D124c of the receiving space 124 can be set according to the maximal radius D910 of the conductive pillar bump 910 and deformability amount of the insulated macromolecular elastomer 121 so as to have an optimum contact effect between the conductive pillar bump 910 and the side walls 124a.

In addition, as shown by a dotted-line region of FIG. 1, the conductive layer 122 has two smooth corners R122. The smooth corners R122 are formed between a bottom and side walls of the receiving space 124, whose curvature radius is larger than 0.05 mm. Due to the design of the smooth corners R122, stress can be more easily accumulated at the smooth corners of the conductive layer 122 to reduce the breaking chance of the conductive layer 122.

The substrate 110 further includes a substrate wiring 111 and a substrate conductive via 112. The conductive layer 122 and the substrate wiring 111 are respectively formed at the two opposite sides of the substrate 110. The substrate conductive via 112 penetrates the substrate 110 to electrically couple the conductive layer 122 to the substrate wiring 111. The conductive macromolecular elastic structure 120 further includes an elastomer conductive via 123. The elastomer conductive via 123 penetrates the insulated macromolecular elastomer 121 to electrically couple the conductive layer 122 to the substrate conductive via 112. The elastomer conductive via 123 and conductive layer 122 are manufactured into a unity. When the conductive pillar bump 910 is inserted into the receiving space 124, the conductive pillar bump 910 and the substrate wiring 111 are electrically coupled to each other via the conductive layer 122, the elastomer conductive via 123 and the substrate conductive via 112.

In the following description, a method of testing a semiconductor element of the embodiment is illustrated in details. Referring to FIG. 1 and FIG. 2, after the conductive pillar bump 910 is positioned well on a wafer of chip, the conductive pillar bump 910 of the chip can be inserted into the receiving space 124 defined by the above conductive macromolecular elastic structure 120 before or after the chip is cut such that the conductive device 900 can be mechanically or electrically coupled to the substrate wiring 111 via the conductive pillar bump 910, conductive macromolecular elastic structure 120, elastomer conductive via 123 and substrate conductive via 112. Then, the test device 100 is connected to a test equipment, that is, automatic test equipment (ATE).

Through the electrically coupling, the test device can test the semiconductor element 900 by using the power supplied by the test equipment to determine whether it matches the required specification. The conductive device 900 can be coupled to the substrate wiring 111 by current, voltage or signal (0/1) coupling. When the ATE receives signals from the semiconductor element 900, the ATE determines whether the semiconductor element 900 has a normal operation according to the predetermined specification. Then, the quality of the semiconductor element 900 is denoted in a way of physics or electricity according to the function determination result for the next process.

The substrate wiring 111 can also be coupled to an application terminal of a printed circuit board (PCB) for an application test in addition to the ATE.

Therefore, the test method can perform a wafer level test before the wafer is cut without need to wait until the chip is fabricated, which largely reduces fabrication cost for chips of poor quality.

In a practical test process, the conductive pillar bump 910 of the semiconductor element 900 is not necessary to mechanically contact with the conductive macromolecular elastic structure 120. They can also contact with each other just through signal transmission. The key point is that through the signal coupling between the conductive macromolecular elastic structure 120 and the conductive pillar bump 910, the test equipment can receive the signals from the semiconductor element 900 and accordingly determine quality of the semiconductor element 900.

In the following description, a method of manufacturing the semiconductor-element test device 100 according to the first embodiment of the invention is illustrated accompanied with a flowchart and structure diagram.

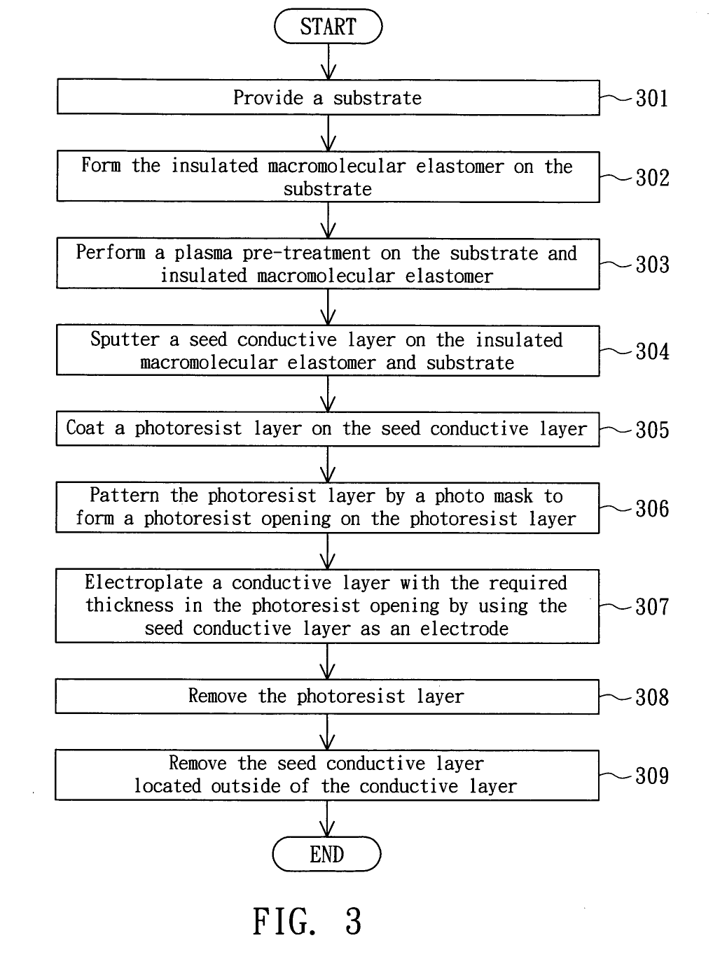

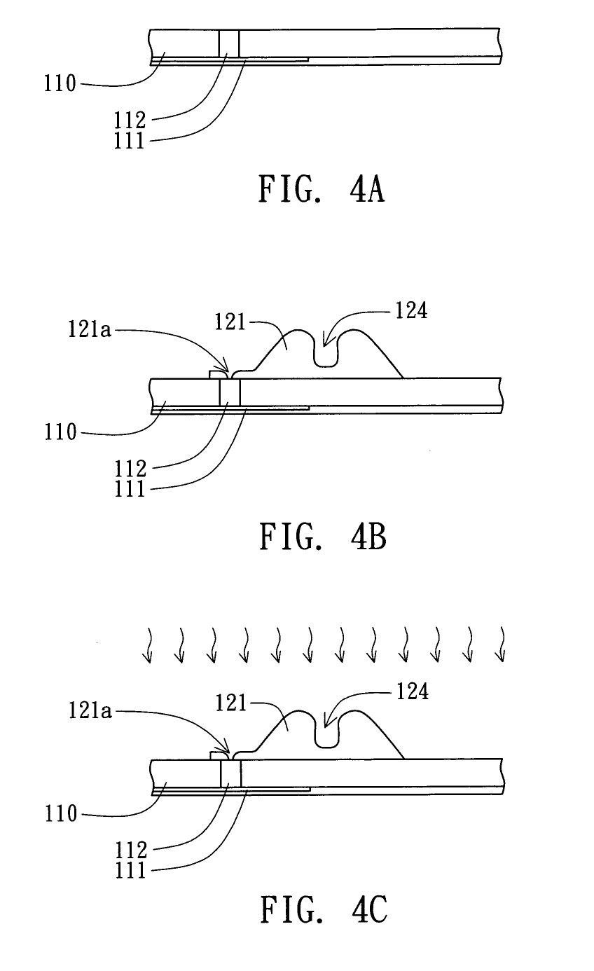

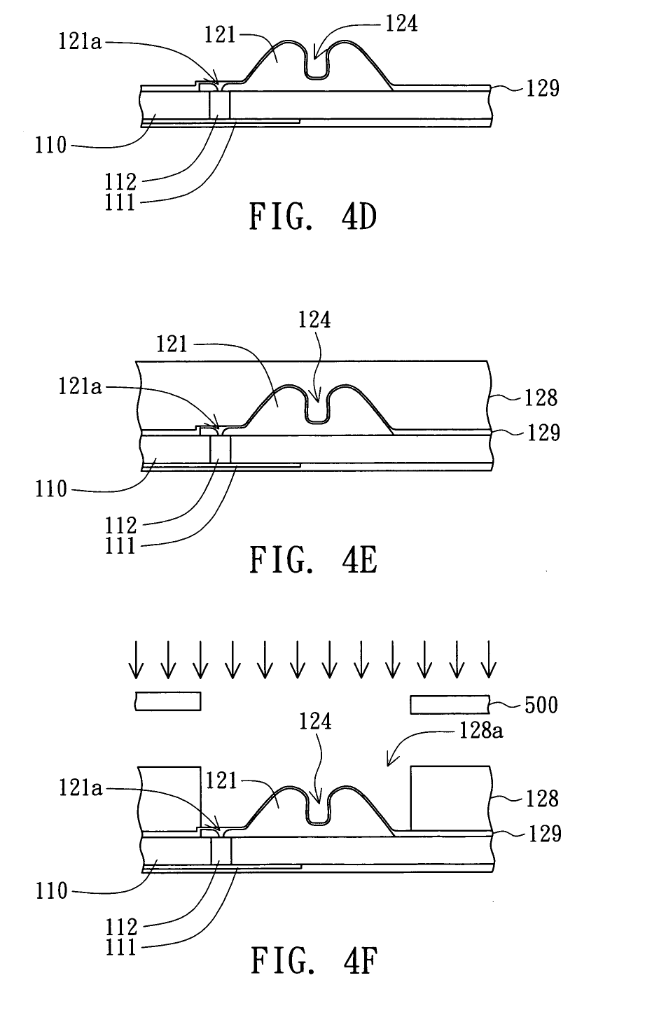

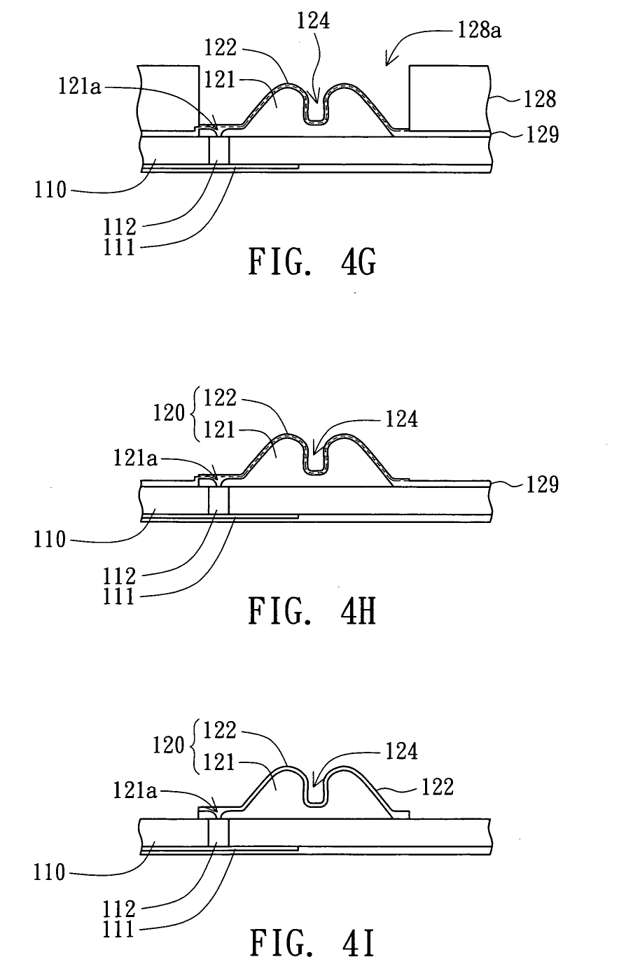

Referring to FIG. 3 and FIGS. 4A˜4I, FIG. 3 is;a flowchart of the method of manufacturing the semiconductor-element test device 100 according to the first embodiment of the invention, and FIGS. 4A˜4I are schematic diagrams of the steps in FIG. 3. In the embodiment, the method of manufacturing the semiconductor-element test device 100 is illustrated by FIG. 3 and FIGS. 4A˜4I as an example. However, any one who is skilled in the related art will realize that the method of manufacturing semiconductor-element test device 100 of the invention is not limited thereto.

First, Referring to FIG. 4A, in step 301, provide a substrate 110. The substrate 110 of the embodiment is selected from a group of a ceramics substrate and a fiberglass substrate (FR4). The substrate 110 includes a substrate wiring 111 and a substrate conductive via 112. The substrate conductive via 112 penetrates two opposite surfaces of the substrate 110.

Next, the steps 302˜309 are performed to form a conductive macromolecular elastic layer on the substrate 110. The conductive macromolecular elastic layer can be a single-layer structure or a multi-layer structure. In the embodiment, the conductive macromolecular elastic layer is a multi-layer structure and consists of an insulated macromolecular elastomer and a conductive layer. The steps 302˜309 are described as below:

Referring to FIG. 4B, in the step 302, form the insulated macromolecular elastomer 121 on the substrate 110. The insulated macromolecular elastomer 121 is made of a material selected from a group of PDMS, rubber and their combination. The insulated macromolecular elastomer 121 can be formed by casting or by patterning (either patterning and etch or using photodefinable material). The better method can be selected to form the insulated macromolecular elastomer 121 according to its composition material.

In the embodiment, the insulated macromolecular elastomer 121 has a two-peak structure and the receiving space 124 is formed between the two peaks. The insulated macromolecular elastomer 121 has an elastomer opening 121a and the elastomer opening 121a exposes the substrate conductive via 112.

Referring to FIG. 4C, in the step 303, perform a plasma pre-treatment on the substrate 110 and insulated macromolecular elastomer 121. The step is used to ensure the surface of the insulated macromolecular elastomer 121 is clean. If the insulated macromolecular elastomer 121 is not clean, the contact between the conductive layer 122 (shown in FIG. 1 and FIG. 2) and the insulated macromolecular elastomer 121 will possibly be affected. In a serious situation, after the conductive pillar bump 910 (shown in FIG. 1 and FIG. 2) is inserted into and pulled out from the receiving space 124 for many times, the conductive layer 122 may be easily loosened from the insulated macromolecular elastomer 121.

Referring to FIG. 4D, in the step 304, sputter a seed conductive layer 129 on the insulated macromolecular elastomer 121 and substrate 110. The seed conductive layer 129 is sputtered on the whole surface of the insulated macromolecular elastomer 121 and substrate 110. In the step 304, owing that the sputtering process has a low deposition speed, and the seed conductive layer 129 is used as a seed layer for the next electroplating process, only a thin seed conductive layer 129 is needed to be formed by sputtering. Although the sputtering process takes more time, owing that only thin seed conductive layer 129 is needed, the step 304 takes not much process time.

Besides, in the step 304, the seed conductive layer 129 is further formed in the elastomer opening 121a. That is, the seed conductive layer 129 is electrically coupled to the substrate wiring 111 at the other side through the substrate conductive via 112.

The seed conductive layer 129 is made of a material selected from a group of titanium (Ti), copper (Cu), an alloy of titanium and copper and their combination.

Referring to FIG. 4E, in the step 305, coat a photoresist layer 128 on the seed conductive layer 129.

Referring to FIG. 4F, in the step 306, pattern the photoresist layer 128 by a photo mask 500 to form a photoresist opening 128a on the photoresist layer 128. The photoresist opening 128a exposes not only the receiving space 124 but also a region of the substrate conductive via 121.

Referring to FIG. 4G, in the step 307, electroplate a conductive layer 122 with the required thickness in the photoresist opening 128a by using the seed conductive layer 129 as an electrode. The conductive layer 122 is made of a material selected from a group of titanium (Ti), copper (Cu), an alloy of titanium and copper and their combination. Generally speaking, the electroplating speed is larger than the sputtering speed and thus a majority of conductive layer 122 can be formed in the step 307.

Referring to FIG. 4H, in the step 308, remove the photoresist layer 128.

Referring to FIG. 4I, in the step 309, remove the seed conductive layer 129 located outside of the conductive layer 122. By performing the steps 304˜309, the conductive layer 122 is formed on the insulated macromolecular elastomer 121. The conductive macromolecular elastic element 120 including the conductive layer 122 and insulated macromolecular elastomer 121 can be formed by performing the above steps.

### Embodiment Two

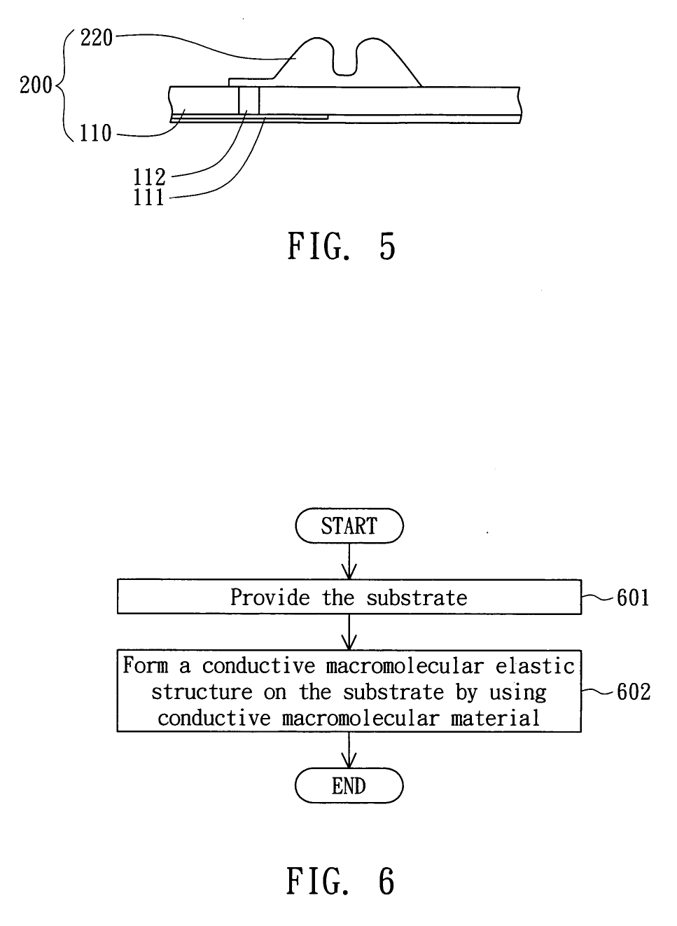

The embodiment discloses a semiconductor-element test device 200 and manufacturing method thereof. Referring to FIG. 5, a schematic diagram of the semiconductor-element test device 200 according to the second embodiment of the invention is shown. Different from the semiconductor-element test device 100 and manufacturing method thereof in the first embodiment, the conductive macromolecular elastic structure 220 of the semiconductor-element test device 200 is directly formed by a conductive macromolecular material.

The conductive macromolecular material is a macromolecular material with electric conductivity close to metal conductivity. Compared to the metal, the macromolecular material has advantages of low density, low cost and high finishing capability. Generally speaking, the conductive macromolecular material can be divided into a pure conductive macromolecular material and a compound conductive macromolecular material. The pure conductive macromolecular material has electric conductivity due to π-bond electrons and mainly includes polyethylene, polythiophene, polypyrrole and polyanaline conductive macromolecular material. The compound conductive macromolecular material is formed to have electric conductivity by adding metal or a carbon conductive additive such as active carbon, carbon fiber and carbon nanotube in the macromolecular.

The conductive macromolecular material has both electric conductivity and elasticity, which simplifies the manufacturing process of semiconductor-element test device 200. The following description illustrates the method of manufacturing the semiconductor-element test device 200 of the embodiment in details by accompanying with a flowchart and schematic diagrams of the steps in the flowchart.

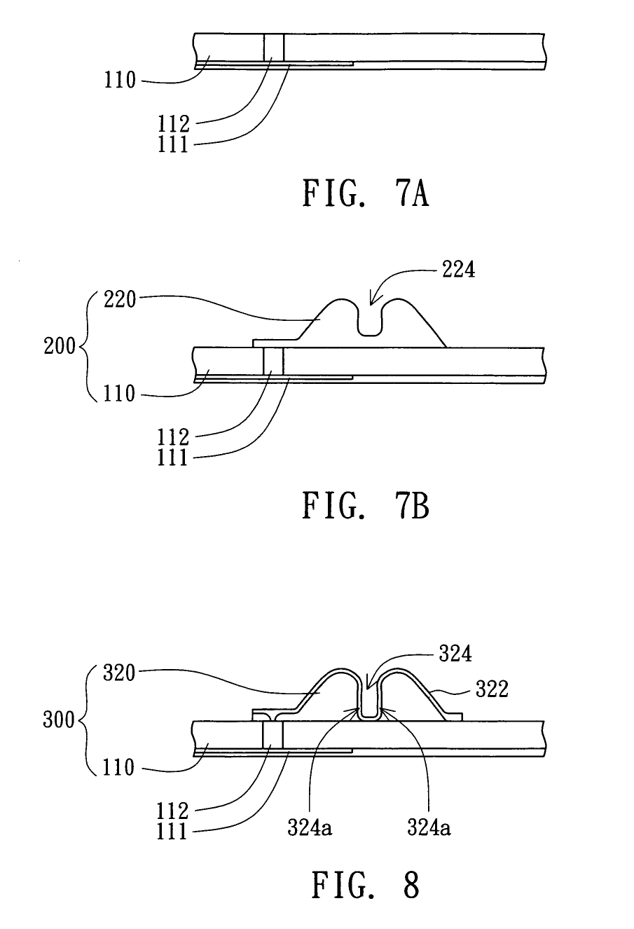

Referring to FIG. 6 and FIGS. 7A˜7B, FIG. 6 is a flowchart of the method of manufacturing the semiconductor-element test device 200 according to the second embodiment of the invention, and FIGS. 7A˜7B are schematic diagrams of the steps in FIG. 6.

First, as shown in FIG. 7A, in step 601, provide the substrate 110.

Next, as shown in FIG. 7B, in step 602, form a conductive macromolecular elastic structure 220 on the substrate 110 by using conductive macromolecular material. In the step 602, the conductive macromolecular material is used to directly form the conductive macromolecular elastic structure 220 having a receiving space 224. Therefore, the conductive macromolecular elastic structure 200 has no elastomer conductive via. When the conductive pillar bump of a semiconductor element is inserted into the receiving space 224, the conductive pillar bump contacts with the conductive macromolecular elastic structure 220 and is electrically coupled to the substrate wiring 111 directly via the conductive macromolecular elastic structure 220 and substrate conductive via 121.

Besides, as for any one who is familiar with the related art, it can be realized that the invention is not limited by the above embodiment. As shown in FIG. 8, the substrate 110 can also be exposed through the receiving space 324. The conductive layer 322 is formed along the two opposite side walls 324a of the receiving space 324 and the substrate 110.

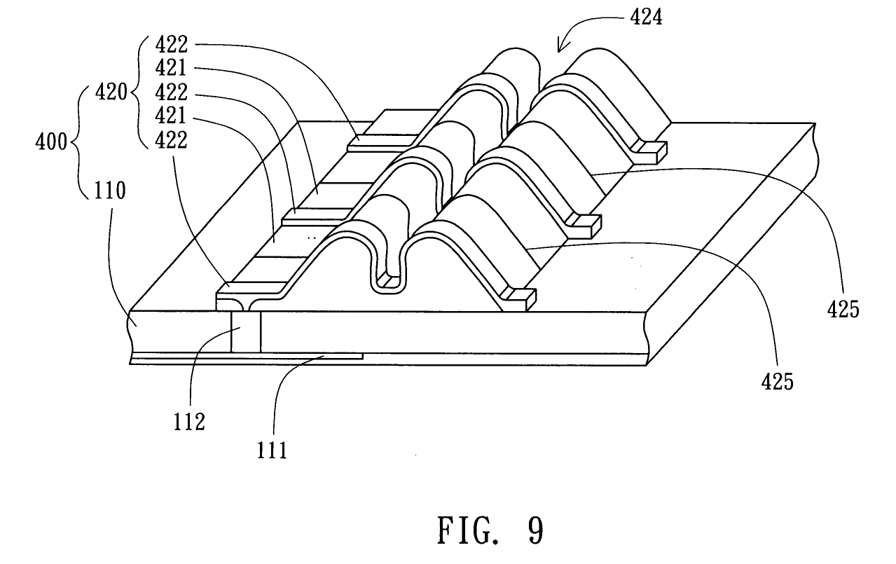

In order to test a number of conductive pillar bumps of the semiconductor chip at a time, a semiconductor-element test device 400 with a number of conductive macromolecular elastic structures 420 is provided as shown in FIG. 9. The semiconductor-element test device 400 consists of several conductive macromolecular elastic structures 420 aligned in parallel. Each conductive macromolecular elastic structure 420 is corresponding to a conductive pillar bump (not shown in FIG. 9). Each conductive macromolecular elastic structure 420 defines a receiving space 424, which is a long shape structure in parallel with the substrate 110.

Each conductive macromolecular elastic structure 420 includes a conductive layer 422 and an insulated macromolecular elastomer 421. The conductive layer 422 is formed on the insulated macromolecular elastomer 421. The conductive layers 422 are electrically separated from each other by a gap. The insulated macromolecular elastomers 421 are separated from each other in structure by a break 425. That is, the conductive macromolecular elastic structures 420 are separated from each other in structure and electricity.

When the conductive pillar bump is inserted into the conductive macromolecular elastic structure 420, owing that the conductive macromolecular elastic structures 420 are separated from each other in structure, the conductive macromolecular elastic structures 420 will not affect each other and thus the conductive pillar bump can contact with the corresponding conductive macromolecular elastic structure 420 very well.

Moreover, owing that the conductive macromolecular elastic structures 420 are electrically separated from each other, when the conductive pillar bump is inserted into the corresponding conductive macromolecular elastic structure 420, there is no shortcut occurred.

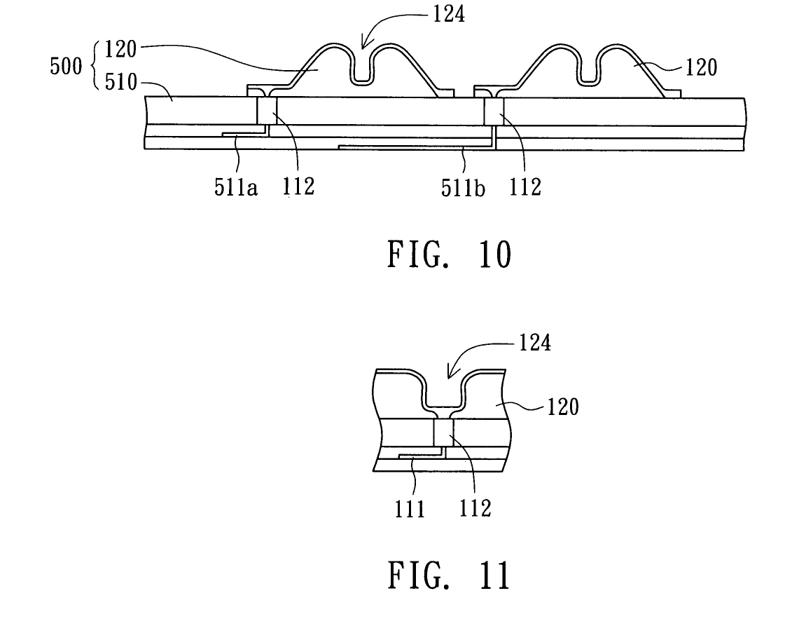

Referring to FIG. 10, in the embodiment of the invention, inner wires 511a and 511b of the substrate 510 can be directly disposed under the receiving space 124. The inner wire 511a of the substrate 510 can also be stretched to a position on another layer.

In addition, owing that the inner wires 511a and 511b can stretch outwards, they can also be directly coupled to the substrate conductive via and the distance between the inner wires 511a and 511b is smaller than that of the wires on the test board. The stretched wires can be arranged by a fan-out pattern to elongate the distance of wires on the test board and thus the test equipment with lower line-width requirement can be used.

Referring to FIG. 11, in the above embodiment, although the insulated macromolecular elastomer 121 has a two-peak structure, it is not limited thereto. The insulated macromolecular elastomer 121 can also have a flat top as long as the receiving space 124 can be formed on the conductive macromolecular elastic structure 120 for inserting the conductive pillar bump of the semiconductor element 900 to electrically couple with the conductive macromolecular elastic structure 120. The conductive pillar bump can directly couple with the substrate wiring 111 through the receiving space 124 and the substrate conductive via 112 without need of the elastomer conductive via 123.

In the apparatus and method of testing semiconductor element and method of manufacturing test device disclosed by the above embodiment of the invention, a conductive macromolecular elastic structure with electric conductivity and elasticity is used as a conductive pad and thus in the test process of semiconductor element, the semiconductor element can be well electrically coupled to the semiconductor-element test device, which is not affected by the factors of length and width diversity of the conductive pillar bump or substrate wear and tear. Therefore, the accuracy of test process can be largely improved.

While the invention has been described by way of example and in terms of a preferred embodiment, it is to be understood that the invention is not limited thereto. On the contrary, it is intended to cover various modifications and similar arrangements and procedures. For example, the pillar bump is disclosed in the above embodiments is just a kind of electric bump. Other kinds of electric bump can be used in the invention, for example solder bump. The scope of the appended claims therefore should be accorded the broadest interpretation so as to encompass all such modifications and similar arrangements and procedures.

What is claimed is:

1. An apparatus of testing a semiconductor element, comprising:
a substrate; and
a conductive macromolecular elastic structure, disposed on the substrate, wherein the conductive macromolecular elastic structure defines a receiving space for receiving a conductive bump of the semiconductor element in order to test the semiconductor element.

2. The apparatus according to claim 1, wherein the conductive macromolecular elastic structure consists of an insulated macromolecular elastomer and a conductive layer, the insulated macromolecular elastomer is disposed on the substrate and the conductive layer is disposed on the insulated macromolecular elastomer.

3. The apparatus according to claim 2, wherein the insulated macromolecular elastomer is made of a material selected from a group of polydimethylsiloxane (PDMS), rubber, and their combination.

4. The apparatus according to claim 2, wherein the conductive layer is disposed along two opposite side walls of the receiving space.

5. The apparatus according to claim 2, wherein the substrate is exposed through the receiving space, and the conductive layer is formed along the two opposite side walls of the receiving space and the substrate.

6. The apparatus according to claim 2, wherein the substrate comprises:
a substrate wiring, wherein the conductive layer and the substrate wiring are formed at two opposite sides of the substrate; and
a substrate conductive via, penetrating the substrate for electrically coupling the conductive layer to the substrate wiring.

7. The apparatus according to claim 6, wherein the conductive macromolecular elastic structure further comprises:
an elastomer conductive via, penetrating the insulated macromolecular elastomer for electrically coupling the conductive layer to the substrate conductive via.

8. The apparatus according to claim 6, wherein the substrate conductive via is formed under the receiving space.

9. The apparatus according to claim 1, comprising a plurality of conductive macromolecular elastic structures, wherein the conductive macromolecular elastic structures are separated from each other in structure and electricity.

10. The apparatus according to claim 9, wherein each conductive macromolecular elastic structure defines a receiving space and the receiving space is a long shape structure in parallel with the substrate.

11. The apparatus according to claim 1, wherein the conductive macromolecular elastic structure is made of a conductive macromolecular material.

12. The apparatus according to claim 1, wherein the conductive layer has two smooth corners and the smooth corners are formed between a bottom and side walls of the receiving space.

13. The apparatus according to claim 12, wherein the smooth corner has a curvature radius larger than 0.05 mm.

14. A method of manufacturing a semiconductor-element testing apparatus, comprising:
providing a substrate; and
forming a conductive macromolecular elastic layer on the substrate, wherein the conductive macromolecular elastic layer has a receiving space;
wherein the receiving space receives a conductive bump of the semiconductor element in order to test the semiconductor element.

15. The method according to claim 14, wherein the conductive macromolecular elastic layer is a single-layer structure made of a conductive macromolecular material.

16. The method according to claim 14, wherein the conductive macromolecular elastic layer is a multi-layer structure consisted of an insulated macromolecular elastomer and a conductive layer and the step of forming the conductive macromolecular elastic layer further comprises:
forming the insulated macromolecular elastomer on the substrate; and
forming the conductive layer on the insulated macromolecular elastomer.

17. The method according to claim 16, wherein in the step of forming the insulated macromolecular elastomer, the insulated macromolecular elastomer is formed by casting.

18. The method according to claim 16, wherein the material of the insulated macromolecular elastomer is selected from a group of PDMS, rubber, and their combination.

19. The method according to claim 16, wherein after the step of forming the insulated macromolecular elastomer, the method further comprises:
performing plasma pre-treatment on the substrate and the insulated macromolecular elastomer.

20. The method according to claim 16, wherein the step of forming the conductive layer further comprises:
sputtering a seed conductive layer on the insulated macromolecular elastomer and the substrate;
coating a photoresist layer on the seed conductive layer;
patterning the photoresist layer to form a photoresist opening;
electroplating the conductive layer in the photoresist opening by using the seed conductive layer as an electrode;
removing the photoresist layer; and
removing the seed conductive layer located outside of the conductive layer.

21. The method according to claim 20, wherein the substrate comprises a substrate wiring and a substrate conductive via, the conductive layer and the substrate wiring are formed at two opposite sides of the substrate, the substrate conductive via penetrates the substrate and is electrically coupled to the substrate wiring, the insulated macromolecular elastomer has an elastomer opening, the substrate conductive via is exposed through the elastomer opening, and in the step of sputtering the seed conductive layer, the seed conductive layer is formed in the elastomer opening.

22. The method according to claim 21, wherein the photoresist opening exposes a region of the substrate conductive via.

23. The method according to claim 20, wherein the material of the seed conductive layer is selected from a group of titanium (Ti), copper (Cu), an alloy of titanium and copper, and their combination.

24. The method according to claim 14, wherein the material of the substrate is selected form a group of a ceramics substrate and a fiberglass substrate (FR4).

25. An apparatus of testing a semiconductor element, comprising:
a substrate; and
a conductive macromolecular elastic structure, disposed on the substrate, the conductive macromolecular elastic structure comprising:
a receiving device, having two side contact positions, wherein the receiving device can be stretched out by an external force and shrink back as the external force is removed.

26. The apparatus according to claim 25, wherein a receiving space is defined between the two side contact positions of the receiving device.

27. The apparatus according to claim 25, wherein the conductive macromolecular elastic structure consists of an insulated macromolecular elastomer and a conductive layer, the insulated macromolecular elastomer is disposed on the substrate and the conductive layer is formed on the insulated macromolecular elastomer.

28. The apparatus according to claim 27, wherein the material of the insulated macromolecular elastomer is selected from a group of PDMS, rubber and their combination.

29. A method of testing a semiconductor element, comprising:
providing a semiconductor element with at least a conductive bump;
providing a substrate with a conductive macromolecular elastic structure, the conductive macromolecular elastic structure having a receiving space and being electrically coupled to a test equipment;
inserting the conductive bump of the semiconductor element into the receiving space such that the conductive bump and the conductive macromolecular elastic structure form a connection relationship for signal transmission;
supplying power to the semiconductor element such that the semiconductor element can transmit a signal to the test equipment via the conductive macromolecular elastic structure; and
reading the signal by the test equipment and determining whether the semiconductor element has a normal operation according to a predetermined specification.

30. The method according to claim 29, wherein in the step of inserting the conductive bump, the conductive bump is inserted against a side wall of the receiving space to stretch the receiving space.

31. The method according to claim 29, wherein in the step of providing the semiconductor element, the semiconductor element is disposed on a wafer.

32. The method according to claim 29, wherein in the step of providing the semiconductor element, the semiconductor element is a bare chip.

33. The method according to claim 29, wherein the conductive macromolecular elastic structure consists of an insulated macromolecular elastomer and a conductive layer, the insulated macromolecular elastomer is disposed on the substrate and the conductive layer is formed on the insulated macromolecular elastomer.

34. The method according to claim 33, wherein the substrate comprises a substrate wiring and a substrate conductive via, the substrate wiring is disposed at a side opposite to the conductive layer, the substrate conductive via penetrates the substrate to electrically couple the conductive layer to the substrate wiring.

35. The method according to claim 33, wherein smooth corners are formed at a bottom of the receiving space and two sides of the conductive layer.

36. The method according to claim 34, wherein the substrate conductive via is formed under the receiving space.

37. The method according to claim 29, wherein when the conductive bump is inserted into the receiving space, the conductive bump is electrically coupled to the conductive macromolecular elastic structure.
